(19) United States
(12) Patent Application Publication
(10) Pub. No.: US 2021/0199695 A1
(43) Pub. Date: Jul. 1, 2021

(54) High Temperature- Low Leakage Probe Apparatus and Method

(71) Applicant: Spire Manufacturing Inc., Fremont, CA (US)

(72) Inventors: Hai Dau, San Ramon, CA (US); Kothandan Shanmugan, Singapore (SG)

(73) Assignee: Spire Manufacturing Inc., Fremont, CA (US)

(21) Appl. No.: 16/729,389

(22) Filed: Dec. 28, 2019

(51) Int. Cl. G01R 1/073; G01R 31/26

(52) U.S. Cl. CPC G01R 1/07342; G01R 1/07378; G01R 31/2601

(57) ABSTRACT

In one embodiment, the present invention includes an apparatus for contacting a plurality of contact locations of a semiconductor device. The apparatus comprises a ring bottom, a ring top, and plurality of probe members. The ring bottom has a plurality of furrows orchestrated toward the plurality of contact locations. Each probe member of the plurality of probes is aligned within a corresponding furrow of the plurality of furrows in order to contact the plurality of contact locations. The ring top has a plurality of protrusions corresponding to the plurality of furrows. Each protrusion of the plurality of protrusions presses against a length of each corresponding probe member of the plurality of probe members, thereby securing each probe member of the plurality of probe members within the corresponding furrow of the plurality of furrows.

### CROSS REFERENCE TO RELATED APPLICATIONS

Not applicable.

### BACKGROUND

The present invention relates to semiconductor probe apparatus, and in particular, to probe apparatus having low leakage over a wide range of temperature and method of making such an apparatus.

Probe cards and assemblies are used to make electrical contact with the pads of a semiconductor device during wafer sort testing. Probe cards are typically fabricated from a FR-4 PCB (Printed Circuit Board) having metalized fingers which allow a probe ring to be attached. The probe ring supports a pattern of probes aligned and angled to make contact with the pads of the specific semiconductor device. The other end of the probes may protrude out of the probe ring so that the ends may be soldered onto the fingers of the probe card. Having well aligned probes provides for consistent electrical and mechanical contact with the semiconductor device. Inconsistent contact alignment and force may result when temperature (e.g. hot chuck) testing above 100° C. or over a large temperature range. Temperature testing may reduce the life of the probe card.

Smaller semiconductor structures with higher performance have driven probe card technologies to their limits in performance and reliability. Higher frequency devices require less leakage, and the smaller footprint requires more precise probe alignment. Temperature testing of these high performance devices may result in inconsistent probing and inaccurate measurements. In many applications the probe card described above may be incapable of providing the low leakage stable contact required for temperature testing.

Thus, there is a need for improved probe apparatus. The present invention solves these and other problems by providing high temperature-low leakage probe apparatus and method of making same.

### SUMMARY

Embodiments of the present invention include a probe apparatus for contacting a plurality of contact locations of a semiconductor device probe. The probe apparatus comprises a ring bottom, a ring top, and plurality of probe members. The ring bottom has a plurality of furrows orchestrated toward the plurality of contact locations. Each probe member of the plurality of probes is aligned within a corresponding furrow of the plurality of furrows in order to contact the plurality of contact locations. The ring top has a plurality of protrusions corresponding to the plurality of furrows. Each protrusion of the plurality of protrusions presses against a length of each corresponding probe member of the plurality of probe members, thereby securing each probe member of the plurality of probe members within the corresponding furrow of the plurality of furrows.

In yet another embodiment, the probe apparatus further comprises a ring top holder. The ring top holder couples to depress the ring top toward the ring bottom such that the each protrusion of the plurality of protrusions presses against the length of each corresponding probe member of the plurality of probe members.

In one embodiment, the ring top holder couples to the ring bottom such that the ring top and the plurality of probe members are secured between the ring top holder and the ring bottom

In another embodiment, the ring top holder includes a portion which couples to the ring bottom and a flange portion which couples to a probe card surface. The portion of the ring top holder passes through an opening in the probe card to make the plurality of probe members available to the plurality of contact locations.

In yet another embodiment, the plurality of furrows are arranged at angles which fan out to allow the plurality of probe members to be oriented toward a central horizontal proximity of the plurality of contact locations.

In another embodiment, the plurality of furrows are arranged to have a vertical angle of decent to allow the plurality of probes to approach a plane of the plurality of contacts, thereby minimizing a bending required to align the plurality of probes.

In yet another embodiment, the invention includes a method for contacting a plurality of contact locations of a semiconductor device. The method comprises orchestrating, aligning, and pressing. The orchestrating includes orchestrating a plurality of furrows of a ring bottom toward the plurality of contact locations. The aligning includes aligning a plurality of probe members. Each probe member of the plurality of probes is aligned within a corresponding furrow of the plurality of furrows in order to contact the plurality of contact locations. The pressing includes pressing a ring top against the plurality of probe members, the ring top having a plurality of protrusions corresponding to the plurality of furrows. Each protrusion of the plurality of protrusions presses against a length of each corresponding probe member of the plurality of probe members, thereby securing each probe member of the plurality of probe members within the corresponding furrow of the plurality of furrows.

The following detailed description and accompanying drawings provide a better understanding of the nature and advantages of the present invention.

### BRIEF DESCRIPTION OF THE DRAWINGS

FIGS. 1A-1B illustrate an assembly according to one embodiment of the present invention.

FIG. 1C illustrates a detail of the wafer side of an assembly of FIGS. 1A-1B

FIG. 1D illustrates an isometric detail of the assembly of FIG. 1A-1B.

FIG. 1E illustrates a sectioning of the detail of FIG. 1D.

FIG. 1F illustrates a detail of FIG. 1E.

FIG. 2A illustrates a ring bottom according to one embodiment of the invention.

FIG. 2B illustrates a detail of a number of furrows of the ring bottom according to another embodiment of the invention.

FIG. 3 illustrates a ring top according to another embodiment of the invention.

FIG. 4 illustrates a ring top holder according to one embodiment of the invention.

FIG. 5 illustrates a probe carrier bottom according to one embodiment of the invention.

FIG. 6 illustrates a probe carrier top according to one embodiment of the invention.

FIG. 7A illustrates a portion of the probe apparatus according to one embodiment of the invention.

FIG. 7B illustrates a detail of the probe apparatus according to one embodiment of the invention.

### DETAILED DESCRIPTION

Described herein are techniques for high temperature-low leakage probe apparatus and method for making same. In the following description, for purposes of explanation, numerous examples and specific details are set forth in order to provide a thorough understanding of the present invention. It will be evident, however, to one skilled in the art that the present invention as defined by the claims may include some or all of the features in these examples alone or in combination with other features described below, and may further include modifications and equivalents of the features and concepts described herein.

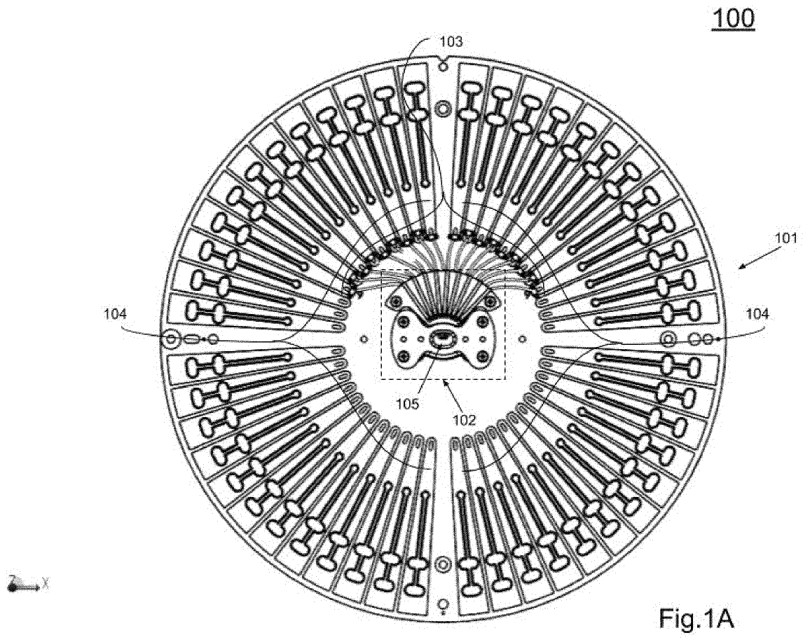

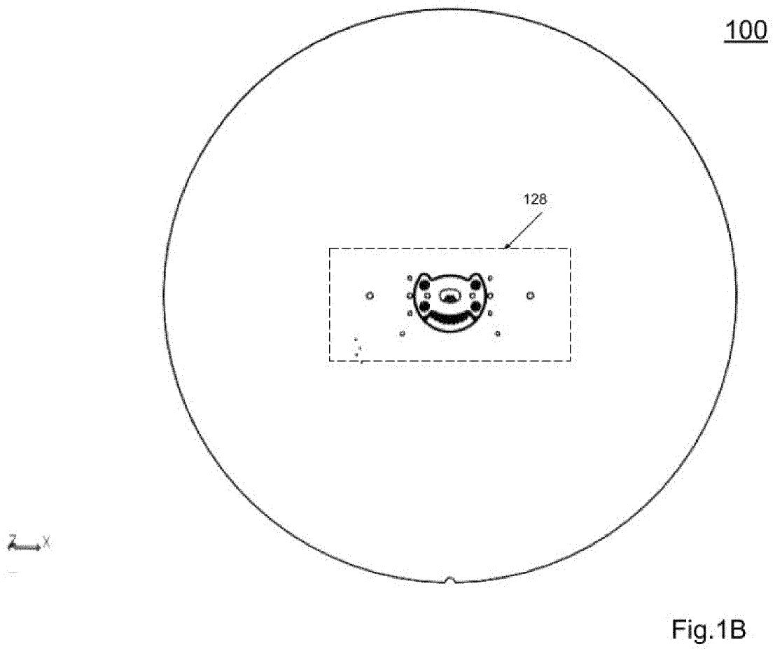

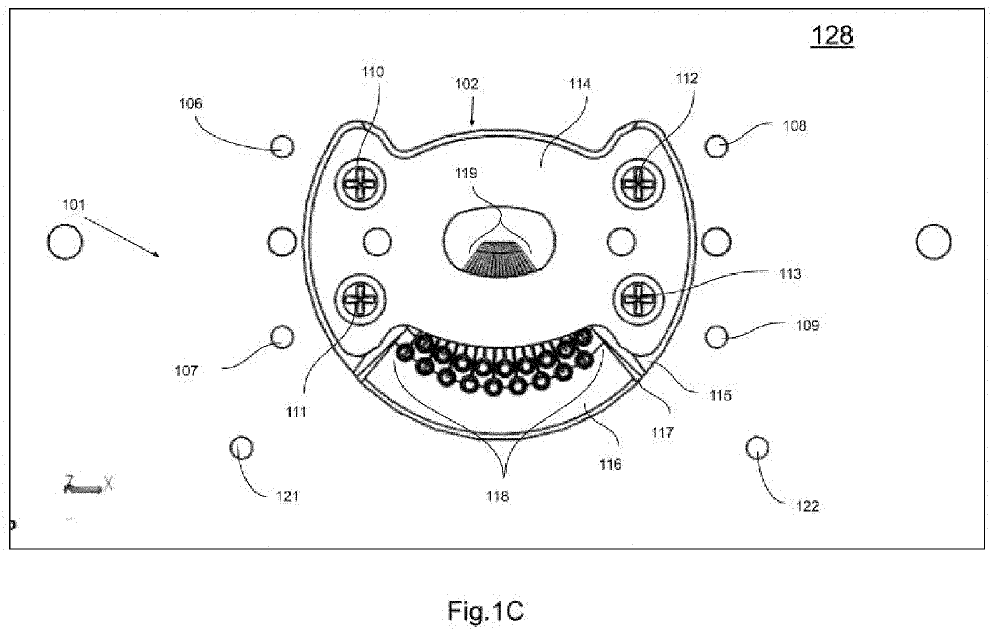

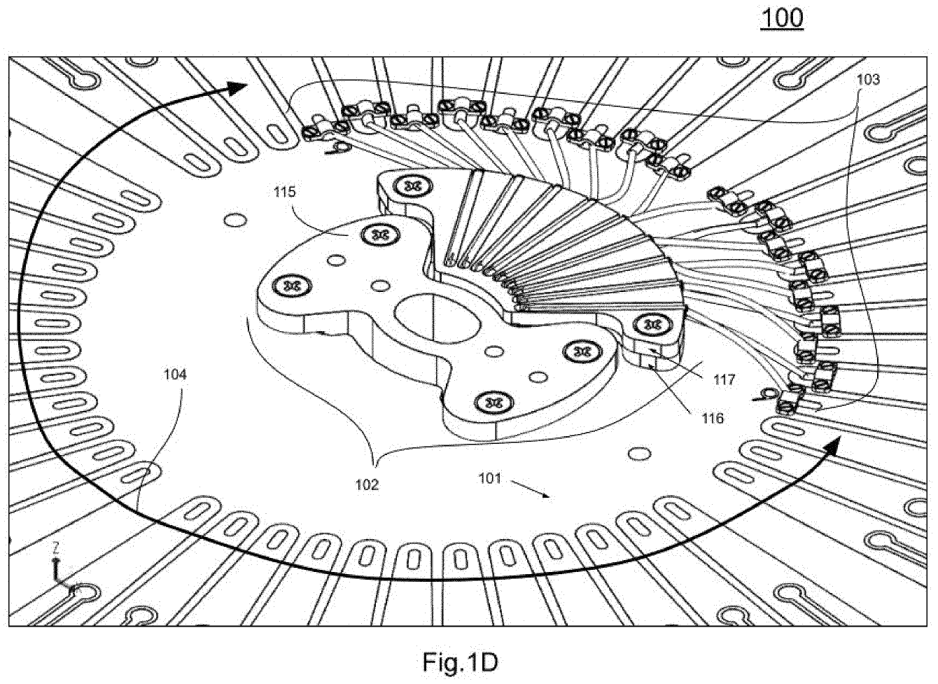

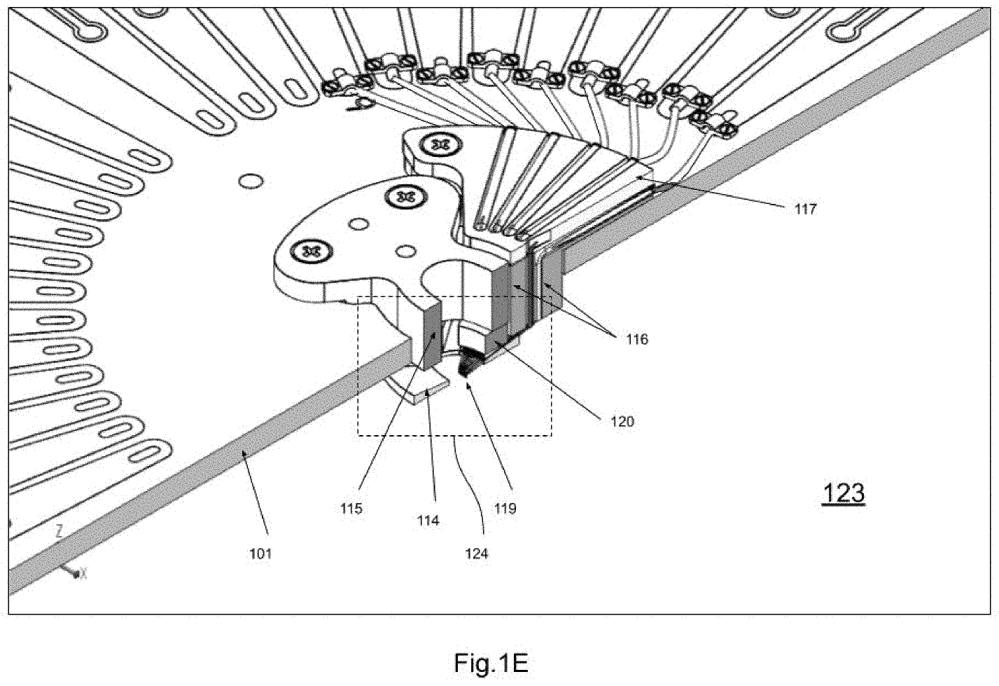

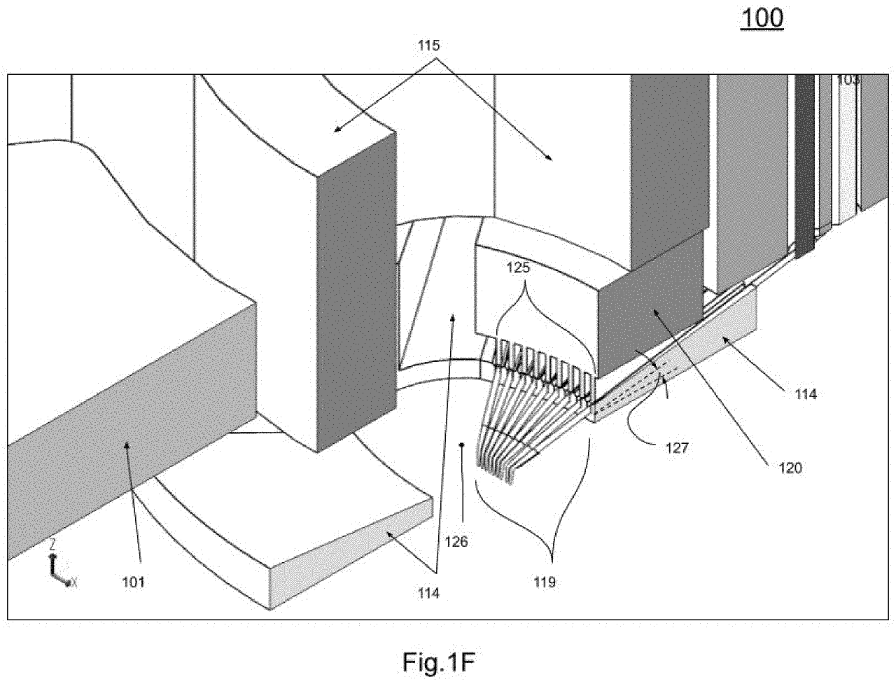

FIGS. 1A-1B illustrate an assembly 100 according to one embodiment of the present invention. Assembly 100 includes a probe card 101, a probe apparatus 102, and a plurality of clamps 103. FIG. 1A illustrates a top view of apparatus 100. Probe card 101 includes a plurality of conductive fingers 104. A plurality of probe members 105 are clamped to their corresponding conductive fingers of the plurality of conductive fingers 104 by corresponding clamps of the plurality of clamps 103. The plurality of clamps 103 may provide an electrical connection to the plurality of probe members without soldering. The probe assembly 100 provides a mechanical rigidity to the plurality of probe tip locations. FIG. 1B illustrates the wafer side of assembly 100 and includes detail 128.

FIG. 1C illustrates a detail 128 of the wafer side of assembly 100 of FIGS. 1A-1B. Detail 128 includes a portion of probe card 101 and holes 106-109 which may be used to attach probe apparatus 102 to probe card 101. Screws 110-113 may be used to connect ring bottom 114 to ring top holder 115. Probe carrier bottom 116 can be seen attached to probe carrier top 117 using holes 121-122. Probe carrier bottom 116 includes a plurality of holes 118 in which a plurality of probe members 119 pass through from the top of assembly 100.

FIG. 1D illustrates an isometric detail of the assembly 100 of FIG. 1A-1B. FIG. 1D illustrates probe card 101, probe apparatus 102, ring top holder 115, probe carrier top 117, and probe carrier bottom 116 as part of assembly 100. A portion of the plurality of conductive fingers 104 and the plurality of clamps 103 are also shown.

FIG. 1E illustrates a sectioning 123 of the detail of FIG. 1D. Probe card 101 includes an opening at its center in which a portion of probe carrier bottom 116 and a portion of ring top holder 115 are inserted. Both probe carrier bottom 116 and ring top holder 115 have a flange with holes in order to attach them to the top of probe card 101. The portion of ring top holder 115 that fits into the probe card 101 hole has threaded holes in which the ring bottom 115 is attached. Ring top 120 is depressed between ring top holder 115 and ring bottom 114. A plurality of probe members 119 are located within corresponding plurality of furrows of ring bottom 114, and protrusions of ring top 120 press down on the plurality of probe members to secure them in place and partially align their trajectory. A finer alignment may be required to match a set of contact locations (not shown) to the tips of the plurality of probe members 119. Box 124 indicates an area for further detail of section 123.

FIG. 1F illustrates further detail 124 of FIG. 1E. FIG. 1F includes an up close look at the sectioning of the hole within probe card 101. Ring top holder 115 is attached to ring bottom 114, and plurality of probe members 119 are depressed by a plurality of protrusions 125 of ring top 120. Plurality of protrusions 125 depress the plurality of members 119 into the plurality of furrows of ring bottom 114. Ring bottom 114 may be tapered such that plurality of probe members 119 approach the ring center 126 at an angle 127. The plurality of furrows may be arranged to have this angle 127 of decent to allow the plurality of probes 119 to approach a plane of the plurality of contacts (not shown), thereby minimizing a bending required to align the plurality of probes 119.

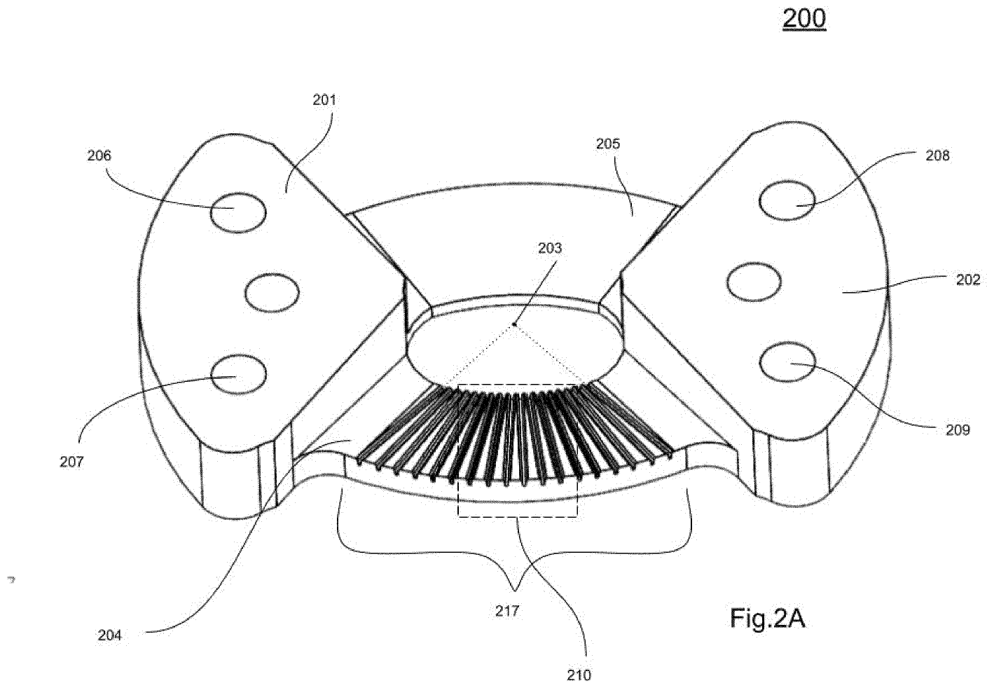

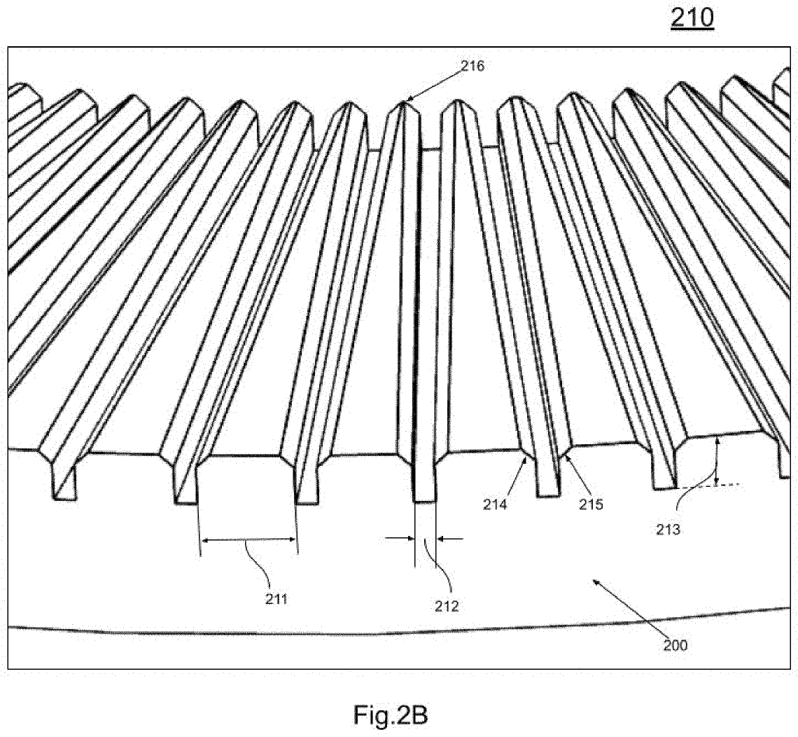

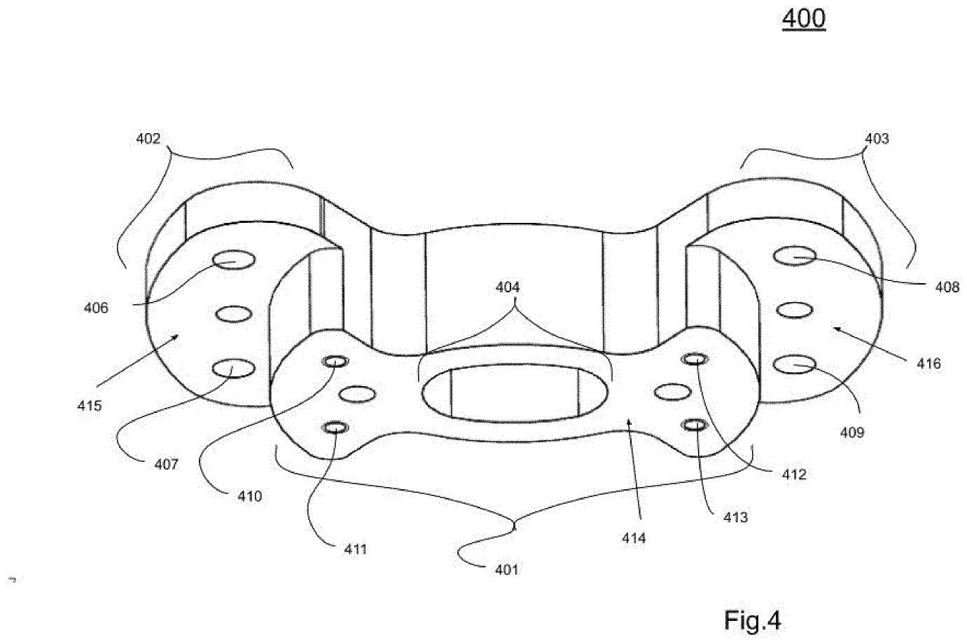

FIG. 2A illustrates a ring bottom 200 according to one embodiment of the invention. Ring bottom 200 includes mating plateau 201-202, ring surface 204-205, plurality of furrows 217, and mounting holes 206-209. Mating plateaus 201-202 fit flush with corresponding surfaces on a ring top holder (e.g. ring top holder 400 of FIG. 4). Mounting holes 206-209 may be counter sunk on the bottom as shown in FIG. 1C to accept flat head screws such that the surface on the bottom is substantially planar without any projections from the screws. Plurality of furrows 217 may be arranged at angles which fan out to allow a plurality of probe members to be oriented toward a central horizontal proximity 203 of a plurality of contact locations (not shown). Plurality of furrows 217 may be arranged to have an angle of decent to allow a plurality of probes to approach a plane of a plurality of contacts, thereby minimizing a bending required to align the plurality of probes. Detail 210 shows a closeup of a number of furrows.

FIG. 2B illustrates detail 210 of a number of furrows of the ring bottom 200 according to one embodiment of the invention. The furrows may have a spacing 211, a width 212, and a depth 213. This width 212 must be greater than or equal to one mil. The depth 213 of each furrow should be sufficient to accommodate a particular gauge of probe wire. For a width 212 of one mil, the minimum of height 213 should be no less than one mil. Different gauges of probe members may be accommodated by having different depths 213 and widths 212 for some furrows as opposed to others. The furrows may be chamfered as indicated at points 214-215. The chamfer may be uniform over the plurality of furrows 205 of ring bottom 200. The chamfer may intersect at point 216 as the spacing 211 narrows. The plurality of furrows may converge to angle all the plurality of probes (not shown) to a general die area.

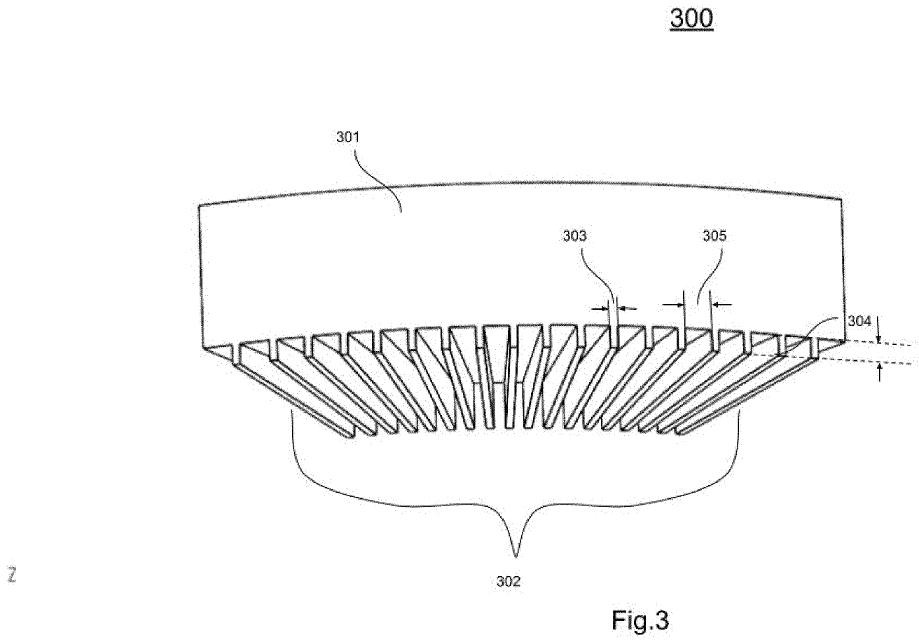

FIG. 3 illustrates a ring top 300 according to another embodiment of the invention. Ring top 300 includes a base portion 301 and a plurality of protrusions 302. Each protrusion may have a width 303 and depth 304. Spacing 305 between protrusions will be governed by the spacing of the plurality of furrows (e.g. plurality of furrows 205 of ring bottom 200 of FIG. 2). Plurality of protrusions 302 should correspond to the plurality of furrows on a ring bottom such that the plurality of protrusions fit within the plurality of furrows in such a way as to secure a particular gauge of probe members.

FIG. 4 illustrates a ring top holder 400 according to one embodiment of the invention. Ring top holder 400 includes a main portion 401, flanges 402-403, an opening 404, board mounting holes 406-409, and ring mounting holes 410-413. Main portion 401 has a single mating plateau 414 to mate to mating plateaus 201-202 of FIG. 2. Flanges 402-403 have surfaces 415-416 respectively which would lay flat on a probe card top and board mounting holes 406-409 would be used to attach flanges 402-403 to the probe card (e.g. probe card 101 of FIG. 1).

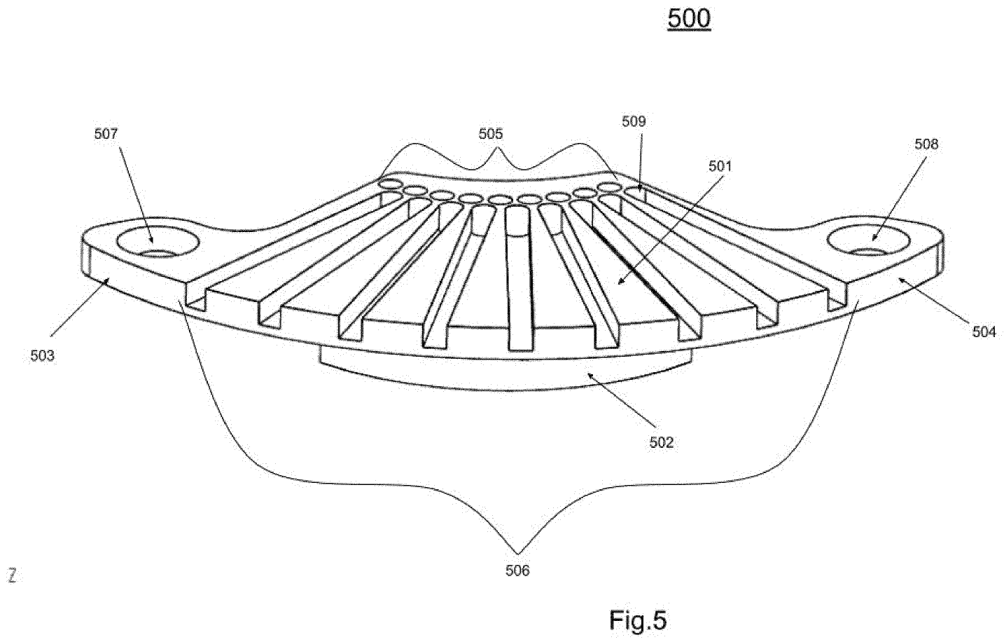

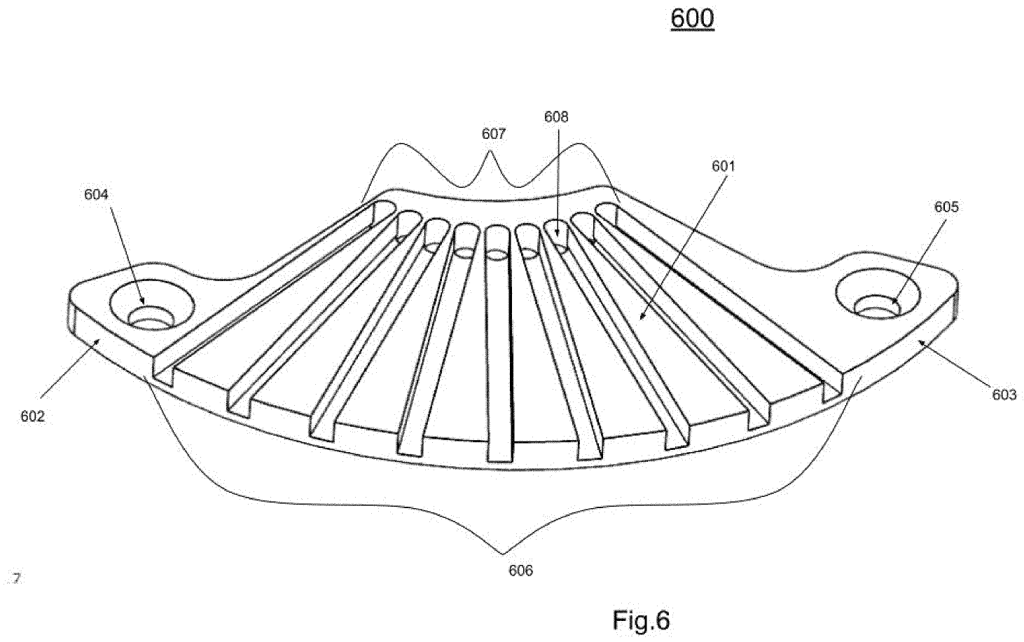

FIG. 5 illustrates a probe carrier bottom 500 according to one embodiment of the invention. Probe carrier bottom 500 includes horizontal carrier portion 501 and vertical carrier portion 502. Horizontal carrier portion 501 includes flanges 503-504 having holes 507-508 (respectively) to couple probe carrier bottom 500 to a probe card (e.g. probe card 101 of FIG. 1A). Horizontal carrier portion also has a plurality of furrows 506 which have a first row of holes at the closed ends of the furrows (e.g. hole location 509). There are also a second row of holes 505. The plurality of furrows 506 guides the probe members horizontally and then vertically down the first row of holes. The second row of holes 505 guides the probe members from the probe carrier top (e.g. probe carrier top 600 of FIG. 6). The first and second row of holes passes through vertical carrier portion 502. Vertical carrier portion 502 is formed to fit into a hole in the probe card. Probe carrier bottom 500 may be manufactured out of ceramic material.

FIG. 6 illustrates a probe carrier top 600 according to one embodiment of the invention. Probe carrier top 600 includes a horizontal carrier portion 601. Horizontal carrier portion 601 includes flanges 602-603 having holes 604-605 (respectively) to couple probe carrier top to probe carrier bottom 500 of FIG. 5 and a probe card (e.g. probe card 101 of FIG. 1A). Horizontal carrier portion 601 also includes a plurality of furrows 606 which have row of holes 607 at the closed ends of plurality of furrows 606 (e.g. hole location 608). The plurality of furrows 606 guides the probe members horizontally and then vertically down the row of holes 607.

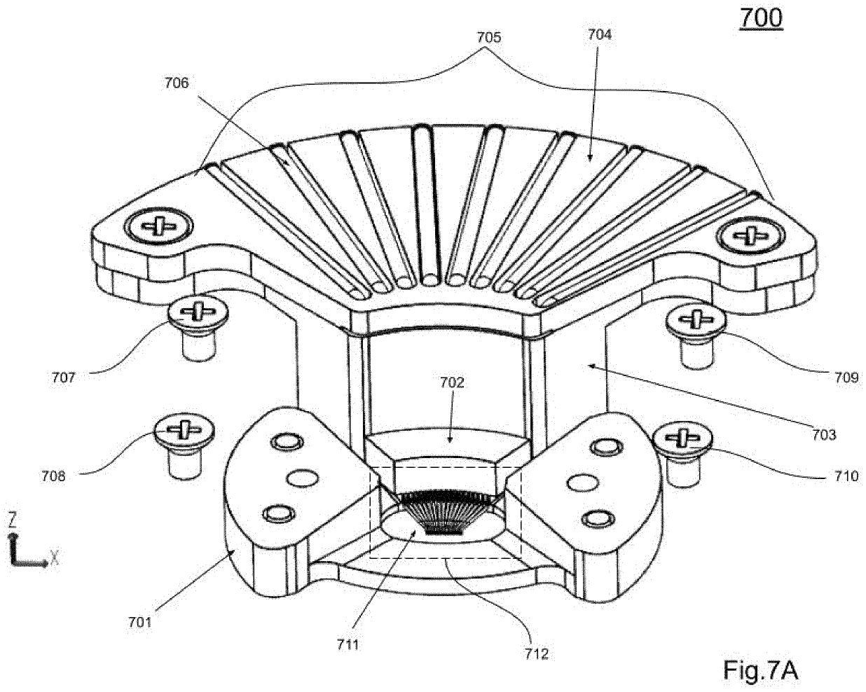

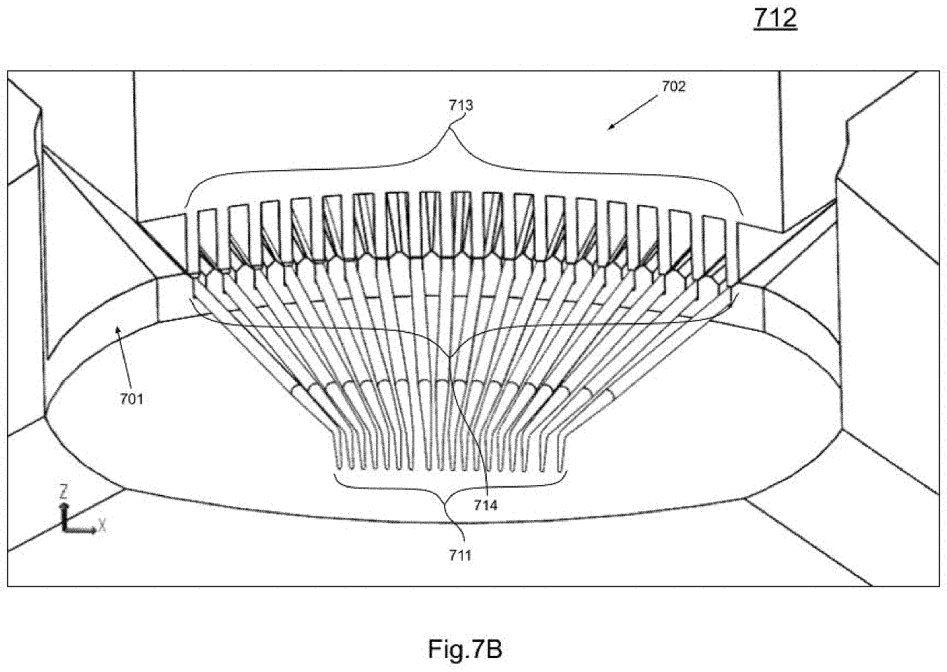

FIG. 7A illustrates a portion of the probe apparatus 700 according to one embodiment of the invention. Probe apparatus 700 includes ring bottom 701, ring top 702, probe carrier bottom 703, probe carrier top 704, ring top holder (not shown) and a plurality of probe members 711. Probe carrier top 704 includes a plurality of furrows with probe carrier tubes 705 (e.g. carrier tube 706). Screws 707-710 floating above ring bottom 701 represent the ring top holder location which was hidden in this figure so that the details of the ring top 702 and ring bottom 701 may be more easily be seen. Detail 712 indicates an area where further particulars of this embodiment may be described.

FIG. 7B illustrates a detail 712 of the probe apparatus 700 according to one embodiment of the invention. Detail 712 illustrates ring bottom 701, ring top 702, and plurality of probe members 711. Ring bottom includes a plurality of furrows 714 orchestrated toward a plurality of contact locations (not shown). Each probe member of the plurality of probes 711 aligned within a corresponding furrow of the plurality of furrows 714 in order to contact the plurality of contact locations. And ring top 702 includes a plurality of protrusions 713 corresponding to the plurality of furrows 714. Each protrusion of the plurality of protrusions 713 presses against a length of each corresponding probe member of the plurality of probe members 711, thereby securing each probe member of the plurality 711 within the corresponding furrow of the plurality of furrows 714.

In one embodiment the ring top 702 is a complete ring which encircles the entire opening of ring bottom 701. In this embodiment, ring bottom 701 would be designed to allow a space for ring top 702 to encircle the entire opening. In another embodiment, there are two separate ring tops and ring bottom 701 would have a second plurality of furrows on the opposite side of the first plurality of furrows.

The above description illustrates various embodiments of the present invention along with examples of how aspects of the present invention may be implemented. The above examples and embodiments should not be deemed to be the only embodiments, and are presented to illustrate the flexibility and advantages of the present invention. Based on the above disclosure, other arrangements, embodiments, implementations and equivalents will be evident to those skilled in the art and may be employed without departing from the spirit and scope of the invention.

What is claimed is:

1. A probe apparatus for contacting a plurality of contact locations of a semiconductor device, said probe apparatus comprising:
a ring bottom having a plurality of furrows orchestrated toward said plurality of contact locations;
a plurality of probe members, each probe member of said plurality of probes aligned within a corresponding furrow of said plurality of furrows in order to contact said plurality of contact locations; and
a ring top having a plurality of protrusions corresponding to said plurality of furrows, wherein each protrusion of said plurality of protrusions presses against a length of each corresponding probe member of said plurality of probe members, thereby securing said each probe member of said plurality of probe members within said corresponding furrow of said plurality of furrows.

2. The probe apparatus of claim 1 further comprising a ring top holder, said ring top holder coupled to depress said ring top toward said ring bottom such that said each protrusion of the plurality of protrusions presses against said length of each corresponding probe member of said plurality of probe members.

3. The apparatus of claim 2 wherein said ring top holder couples to said ring bottom such that said ring top and said plurality of probe members are secured between said ring top holder and said ring bottom.

4. The apparatus of claim 3 wherein said ring top holder includes a portion which couples to said ring bottom and a flange portion which couples to a probe card surface, wherein said portion of said ring top holder passes through an opening in said probe card to make said plurality of probe members available to said plurality of contact locations.

5. The apparatus of claim 1 wherein said plurality of furrows are arranged at angles which fan out to allow said plurality of probe members to be oriented toward a central horizontal proximity of said plurality of contact locations.

6. The apparatus of claim 1 wherein said plurality of furrows are arranged to have a vertical angle of decent to allow said plurality of probes to approach a plane of said plurality of contacts, thereby minimizing a bending required to align said plurality of probes.

7. The apparatus of claim 1 wherein said protrusions are rectangular.

8. The apparatus of claim 1 where said ring top and said ring bottom are ceramic.

9. A method for contacting a plurality of contact locations of a semiconductor device, said method comprising:
orchestrating a plurality of furrows of a ring bottom toward said plurality of contact locations;
aligning a plurality of probe members, each probe member of said plurality of probes aligned within a corresponding furrow of said plurality of furrows in order to contact said plurality of contact locations; and
pressing a ring top against said plurality of probe members, said ring top having a plurality of protrusions corresponding to said plurality of furrows, wherein each protrusion of said plurality of protrusions presses against a length of each corresponding probe member of said plurality of probe members, thereby securing said each probe member of said plurality of probe members within said corresponding furrow of said plurality of furrows.

10. The method of claim 9 wherein said pressing includes a ring top holder coupled to depress said ring top toward said ring bottom such that said each protrusion of the plurality of protrusions presses against said length of each corresponding probe member of said plurality of probe members.

11. The method of claim 10 further comprising coupling said ring top holder to said ring bottom such that said ring top and said plurality of probe members are secured between said ring top holder and said ring bottom.

12. The method of claim 11 further comprises coupling said ring top holder to a probe card surface with a flange portion and a portion of said ring top holder coupling to said ring bottom, wherein said portion of said ring top holder passes through an opening in said probe card to make said plurality of probe members available to said plurality of contact locations.

13. The method of claim 9 further comprising arranging said plurality of furrows at angles which fan out to allow said plurality of probe members to be oriented toward a central horizontal proximity of said plurality of contact locations.

14. The method of claim 9 further comprising arranging said plurality of furrows to have a vertical angle of decent to allow said plurality of probes to approach a plane of said plurality of contacts, thereby minimizing a bending required to align said plurality of probes.

15. A probe assembly for contacting a plurality of contact locations of a semiconductor device, said probe apparatus comprising:
a probe card having a plurality of plurality of conductive fingers; and
a probe apparatus coupled to said probe card, said probe apparatus comprising,
a ring bottom having a plurality of furrows orchestrated toward said plurality of contact locations,
a plurality of probe members, each probe member of said plurality of probes aligned within a corresponding furrow of said plurality of furrows in order to contact said plurality of contact locations, and
a ring top having a plurality of protrusions corresponding to said plurality of furrows, wherein each protrusion of said plurality of protrusions presses against a length of each corresponding probe member of said plurality of probe members, thereby securing said each probe member of said plurality of probe members within said corresponding furrow of said plurality of furrows,
wherein said each plurality of probe members are coupled to a corresponding conductive finger of said plurality of conductive fingers.

16. The assembly of claim 15 further comprising a plurality of clamps which couple said each plurality of probe members to said corresponding conductive finger of said plurality of conductive fingers.

17. The assembly of claim 15 wherein said plurality of furrows are arranged at angles which fan out to allow said plurality of probe members to be oriented toward a central horizontal proximity of said plurality of contact locations.

18. The assembly of claim 15 wherein said plurality of furrows are arranged to have an angle of decent to allow said plurality of probes to approach a plane of said plurality of contacts, thereby minimizing a bending required to align said plurality of probes.

19. The assembly of claim 15 wherein said protrusions are rectangular.

20. The assembly of claim 15 where said ring top and said ring bottom are ceramic.
